(19) United States
(12) Patent Application Publication
(10) Pub. No.: US 2007/0049043 A1
(43) Pub. Date: Mar. 1, 2007

(54) Nitrogen profile engineering in HI-K nitridation for device performance enhancement and reliability improvement

(75) Inventors: Shankar Muthukrishnan, San Jose, CA (US); Rahul Sharangpani, Fremont, CA (US); Tejal Goyani, Sunnyvale, CA (US); Pravin K. Narwankar, Sunnyvale, CA (US); Shreyas S. Kher, Campbell, CA (US); Yi Ma, Santa Clara, CA (US); Giuseppina R. Conti, Oakland, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/209,472

(22) Filed: Aug. 23, 2005

(51) Int. Cl. H01L 21/31

(52) U.S. Cl. 438/758

(57) ABSTRACT

A method and apparatus for forming a nitrided gate dielectric. The method comprises incorporating nitrogen into a dielectric film using a plasma nitridation process to form a nitrided gate dielectric. The first step involves providing a substrate comprising a gate dielectric film. The second step involves inducing a voltage on the substrate. Finally, the substrate is exposed to a plasma comprising a nitrogen source while maintaining the voltage to form a nitrided gate dielectric on the substrate. In one embodiment, the voltage is induced on the substrate by applying a voltage to an electrostatic chuck supporting the substrate. In another embodiment, the voltage is induced on the substrate by applying a DC bias voltage to an electrode positioned adjacent the substrate.

### BACKGROUND OF THE INVENTION

1. Field of the Invention

Embodiments of the present invention generally relate to the field of semiconductor manufacturing. More particularly, embodiments of the invention relate to a method of forming a nitrided gate dielectric layer.

2. Description of the Related Art

Integrated circuits are composed of many, e.g., millions, of devices that function as basic components such as transistors, capacitors, and resistors. Transistors, such as field effect transistors (FET), typically include a source, a drain, and a gate stack. The gate stack typically includes a substrate, such as a silicon substrate, a gate dielectric, such as silicon dioxide, SiO₂, on the substrate, and a gate electrode, such as polycrystalline silicon, on the gate dielectric. The gate dielectric layer generally comprises dielectric materials such as silicon dioxide (SiO₂), or a high-K dielectric material having a dielectric constant greater than 4.0, such as silicon oxynitride (SiON), silicon nitride (SiN), hafnium oxide (HfO₂), hafnium silicate (HfSiO₂), hafnium silicon oxynitride (HfSiON), zirconium oxide (ZrO₂), zirconium silicate (ZrSiO₂), barium strontium titanate (BaSrTiO₃ or BST), lead zirconium titanate (Pb(ZrTi)O₃, or PZT), and other suitable materials.

As integrated circuit sizes and the sizes of the transistors thereon decrease, the gate drive current required to increase the speed of the transistor has increased. Because the gate drive current increases as the gate capacitance increases and capacitance is inversely proportional to the gate dielectric thickness, decreasing the dielectric thickness is one method of increasing the drive current.

Attempts have been made to reduce the thickness of SiO₂ gate dielectrics below 20 Å. However, it has been found that the use of thin SiO₂ gate dielectrics below 20 Å often results in undesirable effects on gate performance and durability. For example, boron from a boron doped gate electrode can penetrate through a thin SiO₂ gate dielectric into the underlying silicon substrate. Also, there is typically an increase in gate leakage, i.e., tunneling, with thin dielectrics thus increasing the amount of power consumed by the gate. Further, thin SiO₂ gate dielectrics may be susceptible to hot carrier damage, in which high energy carriers traveling across the dielectric can damage or destroy the gate. In addition, thin SiO₂ gate dielectrics may also be susceptible to negative bias temperature instability (NBTI), wherein the threshold voltage or drive current drifts with operation of the gate.

One method of forming a dielectric layer suitable for use as the gate dielectric layer in a MOSFET (metal oxide semiconductor field effect transistor) includes nitridizing a thin silicon oxide film in a nitrogen-containing plasma. Increasing the net nitrogen content in the gate oxide to increase the dielectric constant is desirable for several reasons. For example, the bulk of the oxide dielectric may be lightly incorporated with nitrogen during the plasma nitridation process, which reduces the equivalent oxide thickness (EOT) over the starting oxide. The EOT of an alternative dielectric layer in a particular capacitor is the thickness that the alternative dielectric layer would have if its dielectric constant were that of silicon dioxide. This may result in a gate leakage reduction, due to tunneling during the operation of a FET (field effect transistor); at the same time, such increased nitrogen content may also reduce damage induced by tunneling currents during subsequent processing operations. Another benefit of increasing the net nitrogen content of the gate oxide is that the nitridized gate dielectric is more resistant to the problem of gate etch undercut, which in turn reduces defect states and current leakage at the gate edge.

In U.S. Pat. No. 6,610,615 titled “Plasma Nitridation For Reduced Gate Dielectric Layers,” issued on Aug. 26, 2003, McFadden, et al. compared nitrogen profiles in a silicon oxide film for both thermal and plasma nitridation processes (see FIG. 2 of U.S. Pat. No. 6,610,615). The nitrogen profile data for the thermally nitrided oxide shows a first concentration of nitrogen at a top surface of an oxide layer, a generally declining concentration of nitrogen deeper in the oxide, an interfacial accumulation of nitrogen at the oxide-silicon interface, and finally, a nitrogen concentration gradient that is generally declining with distance into the substrate. In contrast, it can be seen that the plasma nitridation process produces a nitrogen profile that is essentially monotonically decreasing from the top surface of the oxide layer through the oxide silicon interface and into the substrate. The undesirable interface accumulation of nitrogen seen with a thermal nitridation process does not occur with the ionic bombardment of the nitrogen plasma. Furthermore, the nitrogen concentration in the substrate is lower, at all depths, than is achieved with the thermal nitridation process.

As mentioned earlier, a benefit of increasing nitrogen concentration at the gate-electrode-gate oxide interface is that dopant, such as boron, out-diffusion from polysilicon gate electrodes into or through the gate oxide is reduced. This improves device reliability by reducing defect states in the bulk of the gate oxide caused by, for example, in-diffused boron from a boron doped polysilicon gate electrode. Another benefit of reducing nitrogen content at the gate-oxide silicon channel interface is the reduction of fixed charge and interface state density. This improves channel mobility and transconductance. Therefore, plasma nitridation processes has advantages over thermal nitridation processes.

However, as device geometry continues to shrink, there remains a need for a method of depositing gate dielectrics that have thinner Electrical Oxide Thickness (EOT) with improved mobility.

### SUMMARY OF THE INVENTION

Embodiments of the present invention generally provide a method of forming a nitrided gate dielectric. The method comprises incorporating nitrogen into a dielectric film using a plasma nitridation process to form a nitrided gate dielectric. The first step involves providing a substrate comprising a gate dielectric film. The second step involves inducing a voltage on the substrate. Finally, while maintaining the voltage, the substrate is exposed to a plasma comprising a nitrogen source to form a nitrided gate dielectric on the substrate. In one embodiment, the voltage is induced on the substrate by applying a voltage to an electrostatic chuck supporting the substrate. In another embodiment, the voltage is induced on the substrate by applying a DC bias voltage to an electrode positioned adjacent the substrate.

Embodiments of the invention also provide a method of forming a nitrided gate dielectric in an integrated processing system. A silicon substrate is introduced into a first processing chamber of the integrated processing system where a dielectric film is formed on the substrate. The substrate is transferred to a second processing chamber of the integrated processing system where the substrate is annealed. The substrate is then transferred to a third processing chamber of the integrated processing system where a voltage is induced on the substrate while exposing the substrate to a plasma comprising a nitrogen source to form a nitrided gate dielectric on the substrate. In another embodiment, the substrate is transferred to the second processing chamber of the integrated processing system where the substrate is annealed. In another embodiment, the substrate is transferred to a fourth processing chamber of the integrated processing system where a polysilicon layer is deposited on the substrate. In another embodiment, the voltage induced on the substrate comprises applying a bias voltage of less than about 1200 V at a pressure of 4 Torr of helium.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a process flow diagram in accordance with the present invention.

FIG. 2 shows a schematic diagram of a plasma reactor according to an embodiment of the present invention.

FIG. 3 is a process flow diagram in accordance with the present invention.

FIG. 4 is a schematic view of an integrated processing system.

FIG. 5A shows oxygen, hafnium, silicon oxide, nitrogen, and silicon concentration profiles for a chuckless plasma nitridation process.

FIG. 5B shows oxygen, hafnium, silicon oxide, nitrogen, and silicon concentration profiles for a chucked plasma nitridation process.

### DETAILED DESCRIPTION

Embodiments of the present invention relate to the formation of high-k dielectric materials over substrates. The high-K dielectric material may have a variety of compositions that are homogenous, heterogeneous, graded and/or multiple layered stacks or laminates. The high-k dielectric material may include combinations of hafnium, zirconium, titanium, tantalum, lanthanum, aluminum, silicon, oxygen and/or nitrogen. High-K dielectric materials may include hafnium containing materials, such as hafnium oxides (HfOₓ or HfO₂), hafnium silicates (HfSiₓO_{y} or HfSiO₄), hafnium, silicon oxynitrides (HfSiₓO_{y}N_{z}), hafnium oxynitrides (HfOₓN_{y}), hafnium aluminates (HfAlₓO_{y}), hafnium aluminum silicates (HfAlₓSi_{y}O_{z}), hafnium aluminum silicon oxynitrides (HfAl_{w}SiₓO_{y}N_{z}), hafnium lanthanum oxides (HfLaₓO_{y}), zirconium containing materials, such as zirconium oxides (ZrOₓ or ZrO₂), zirconium silicates (ZrSiₓO_{y} or ZrSiO₄), zirconium silicon oxynitrides (ZrSiₓO_{y}N_{z}), zirconium oxynitrides (ZrOₓN_{y}), zirconium aluminates (ZrAlₓO_{y}), zirconium aluminum silicates (ZrAlₓSi_{y}O_{z}), zirconium aluminum silicon oxynitrides (ZrAl_{w}SiₓO_{y}N_{z}), zirconium lanthanum oxides (ZrLaₓO_{y}), other aluminum-containing materials or lanthanum-containing materials, such as aluminum oxides (Al₂O₃ or AlOₓ), aluminum oxynitrides (AlOₓN_{y}), aluminum silicates (AlSiₓO_{y}), aluminum silicon oxynitrides (AlSiₓO_{y}N_{z}), lanthanum aluminum oxides (LaAlₓO_{y}), lanthanum oxides (LaOₓ or La₂O₃), other suitable materials, composites thereof, and combinations thereof. Other high-K dielectric materials useful for dielectric layers may include titanium oxides (TiOₓ or TiO₂), titanium oxynitrides (TiOₓN_{y}), tantalum oxides (TaOₓ or Ta₂O₅) and tantalum oxynitrides (TaOₓN_{y}). Laminate films that are useful dielectric materials for high-K dielectric layers include HfO₂/Al₂O₃, HfO₂/SiO₂, La₂O₃/Al₂O₃ and HfO₂/SiO₂/Al₂O₃. The high-K dielectric material preferably comprises hafnium oxide, hafnium silicates, composites thereof, or combinations thereof. Substrates on which embodiments of the invention may be useful include, but are not limited to semiconductor wafers, such as crystalline silicon, silicon oxide, strained silicon, SOI, silicon germanium, doped or undoped polysilicon, doped or undoped silicon wafers, silicon nitride, patterned or non-patterned wafers, and may include materials formed thereover, such as dielectric materials, conductive materials, silicon layers and metal layers.

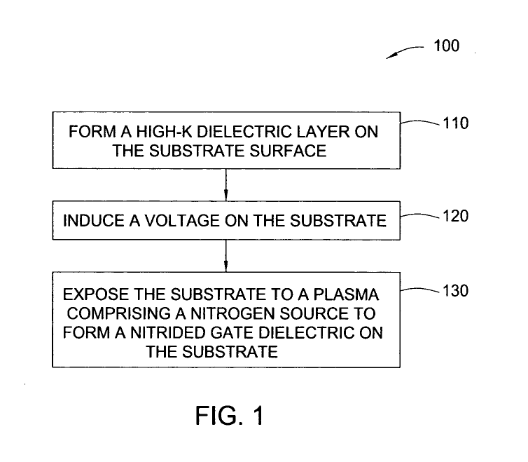

FIG. 1 is a flow chart of one embodiment of a method 100 of forming a nitrided high-K dielectric layer on a substrate surface. In step 110, a high-K dielectric layer is formed on the substrate surface. In step 120, a voltage is induced on the substrate surface. In step 130, while maintaining the voltage, the substrate is exposed to a plasma comprising a nitrogen source to form a nitrided gate dielectric on the substrate surface.

The high-K dielectric layer of step 110 may be deposited on a substrate by conventional deposition techniques such as atomic layer deposition (ALD), chemical vapor deposition (CVD), physical vapor deposition (PVD), thermal and plasma techniques and combinations thereof. In a preferred embodiment, the high-k dielectric layer is deposited by an ALD process and apparatus, such as described in co-pending U.S. Provisional Patent Application Ser. No. 60/570,173, filed May 12, 2004, entitled, “Apparatuses And Methods For Atomic Layer Deposition of Hafnium-containing High-K Dielectric Materials,” assigned to Applied Materials, Inc., and herein incorporated by reference. The high-k dielectric layer is generally deposited with a film thickness from about 10 Å to about 1000 Å, preferably from about 20 Å to about 500 Å and more preferably from about 50 Å to about 200 Å, for example, about 100 Å.

During the Decoupled Plasma Nitridation (DPN) process of step 130, the substrate is bombarded with atomic-N formed by co-flowing N₂ and a noble gas plasma such as argon. Besides N₂, other nitrogen-containing gases may be used to form the nitrogen plasma, such as hydrazines (e.g., N₂H₄ or MeN₂H₃), amines (e.g., Me₃N, Me₂NH or MeNH₂), anilines (e.g., C₅H₅NH₂), and azides (e.g., MeN₃ or Me₃SiN₃). Other noble gases that may be used in a DPN process include helium, neon, and xenon. The nitridation process proceeds at a time period from about 10 seconds to about 360 seconds, preferably from about 30 seconds to about 180 seconds, for example, about 120 seconds. Also, the nitridation process is conducted with a plasma power setting at about 300 watts to about 2,700 watts and a pressure at about 10 mTorr to about 100 mTorr. The nitrogen has a flow rate from about 0.1 slm to about 1.0 slm. The individual and total gas flows of the processing gases may vary based upon a number of processing factors, such as the size of the processing chamber, the temperature of the processing chamber, and the size of the substrate being processed. In a preferred embodiment, the nitridation process is a DPN process and includes a plasma formed by co-flowing Ar and N₂.

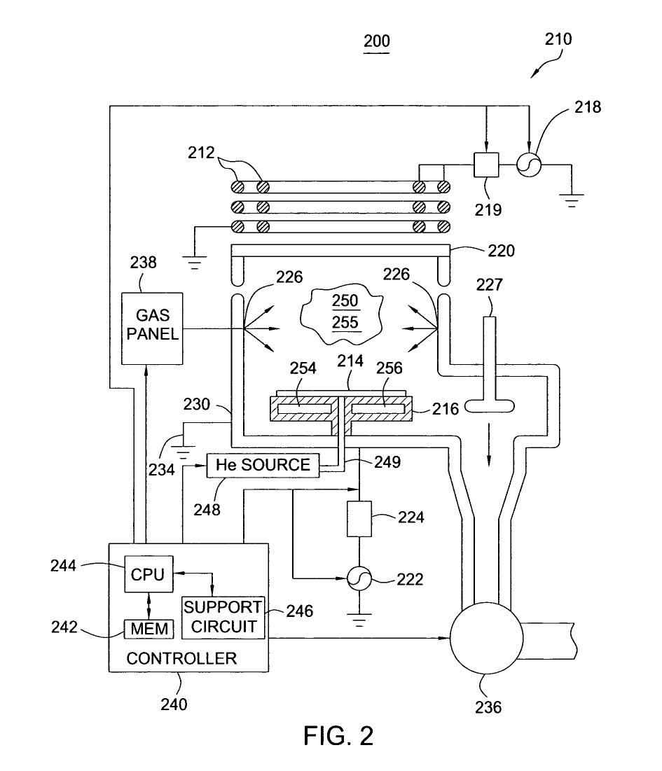

FIG. 2 depicts a schematic, cross sectional diagram of a DPN process reactor 200, made by Applied Materials located in Santa Clara, Calif. It is an inductive plasma source reactor that is one example of a reactor that may be used to practice the present invention.

The reactor 200 comprises a process chamber 210 having an electrostatic chuck 216 within a conductive body (wall) 230, and a controller 240. The chamber 210 is supplied with a substantially flat dielectric ceiling 220. Other modifications of the chamber 210 may have other types of ceilings, e.g., a dome-shaped ceiling. Above the ceiling 220 is disposed an antenna comprising at least one inductive coil element 212 (two co-axial elements 212 are shown). The inductive coil element 212 is coupled, through a first matching network 219, to a plasma power source 218. The plasma power source 218 typically is capable of producing up to 3000 W at a tunable frequency in a range from 50 kHz to 13.56 MHz.

The electrostatic chuck 216 includes a first electrode 254 and a second electrode 256 embedded in a dielectric material. The first electrode and second electrode are biased with DC potentials to provide the chucking action that holds the substrate 214. Application of the chucking voltage to the electrostatic chuck 216 and wafer spacing mask produces charge distribution along the underside of the substrate 214 and over the surface of the electrostatic chuck 216. The opposite polarity of these charges produces an attractive electrostatic force between the substrate 214 and the electrostatic chuck 216. This force retains the substrate 214 upon the chuck without relying upon a plasma within the processing chamber to provide a conductive grounding path for the substrate 214. The electrostatic chuck 216 may also be a monopolar chuck.

Details of the monopolar electrostatic chuck are described in U.S. Pat. No. 5,982,607, entitled “Monopolar Electrostatic Chuck Having An Electrode In Contact With A Workpiece,” assigned to Applied Materials, Inc., issued Nov. 9, 1999, and herein incorporated by reference to the extent not inconsistent with the invention. Another example of an electrostatic chuck is described in U.S. Pat. No. 5,315,473, entitled “Technique For Improving Chucking Reproducibility,” assigned to Applied Materials, Inc., issued May 24, 1994 and herein incorporated by reference to the extent not inconsistent with the invention.

The electrostatic chuck 216 is coupled, through a second matching network 224, to a biasing power source 222. The biasing power source 222 is generally capable of producing a RF signal having a tunable frequency of 50 kHz to 13.56 MHz and a power of between 0 and 5000 watts. Optionally, the biasing power source 222 may be a DC or pulsed DC source. A controller 240 comprising a central processing unit (CPU) 244, a memory 242, and support circuits 246 for the CPU 244 and facilitates control of the components of the chamber 210 and, as such, of the nitridation process as discussed.

In another embodiment, the voltage for operating the electrostatic chuck 216 can be supplied by a separate “chuck” power supply (not shown). One output terminal of the chucking power supply is connected to the chuck electrode. The other output terminal typically is connected to electrical ground, but alternatively may be connected to a metal body portion of the electrostatic chuck 216. In operation, the substrate is placed in contact with the dielectric material, and a direct current voltage is placed on the electrode to create the electrostatic attractive force or bias to adhere the substrate on the upper surface of the electrostatic chuck 216.

In operation, a semiconductor wafer 214 is placed on the electrostatic chuck 216 and process gases are supplied from a gas panel 238 through entry ports 226 to form a gaseous mixture 250. The gaseous mixture 250 is ignited to form a plasma 255 in the chamber 210 by applying power from the plasma source 218. The pressure within the interior of the chamber 210 is controlled using a throttle valve 227 and a vacuum pump 236. Typically, the chamber wall 230 is coupled to an electrical ground 234. The temperature of the wall 230 is controlled using liquid-containing conduits (not shown) that run through the wall 230.

The temperature of the substrate 214 is controlled by stabilizing a temperature of the electrostatic chuck 216. In one embodiment, helium gas from a gas source 248 is provided via a gas conduit 249 to channels (not shown) formed in the surface of the electrostatic chuck 216 to a fine space (not shown) formed between the reverse surface of the substrate 214 and the upper surface of the electrostatic chuck 216. During processing, the electrostatic chuck 216 may be heated by a resistive heater (not shown) within the pedestal of the electrostatic chuck 216 to a steady state temperature and then the helium gas facilitates uniform heating of the substrate 214. Using such thermal control, the substrate 214 is maintained at a temperature between about 200° C. to 350° C.

To facilitate control of the process chamber 210 as described above, the controller 240 may be one of any form of general-purpose, computer processor that can be used in an industrial setting for controlling various chambers and sub-processors. The memory 242, or computer-readable medium, of the CPU 244 may be one or more of readily available memory such as random access memory (RAM), read only memory (ROM), floppy disk, hard disk, or any other form of digital storage, local or remote. The support circuits 246 are coupled to the CPU 244 for supporting the processor in a conventional manner. These circuits include cache, power supplies, clock circuits, input/output circuitry and subsystems, and the like. The inventive method is generally stored in the memory 242 as a software routine. The software routine may also be stored and/or executed by a second CPU (not shown) that is remotely located from the hardware being controlled by the CPU 244.

Other details of the Decoupled Plasma Nitridation process reactor 400 are described in U.S. Patent Application Publication No. 2004/0242021, entitled “Method And Apparatus For Plasma Nitridation Of Gate Dielectrics Using Amplitude Modulated Radio Frequency Energy,” assigned to Applied Materials, Inc., published Dec. 2, 2004 and herein incorporated by reference to the extent not inconsistent with the invention. Examples of suitable DPN chambers include the DPN Centura™, which is commercially available from Applied Materials, Inc., Santa Clara, Calif.

Integrated Processing Sequence

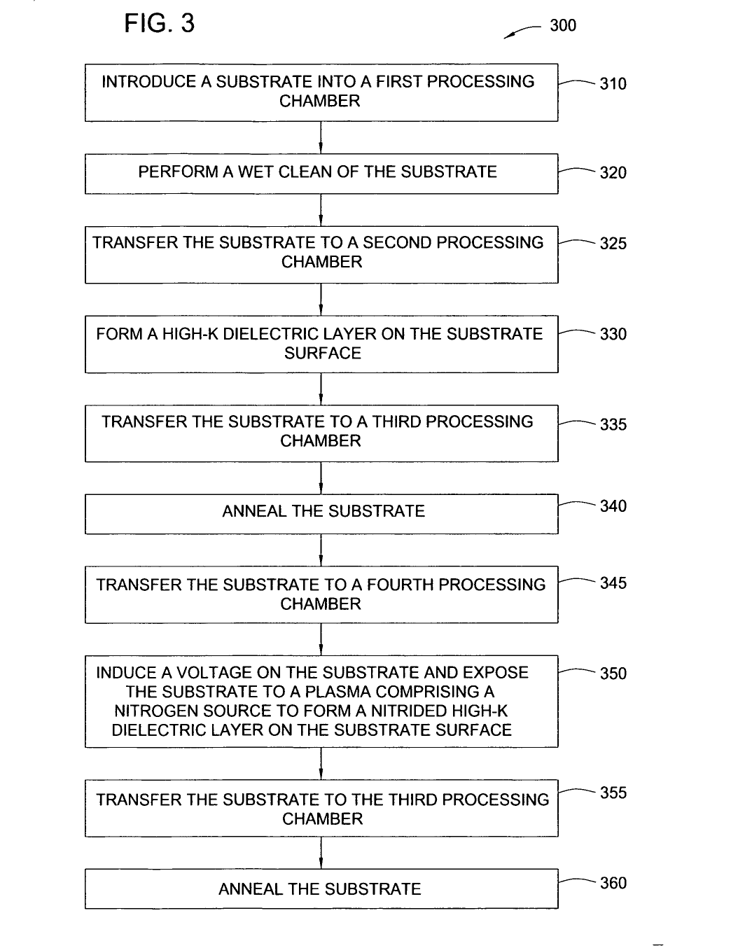

FIG. 3 is one embodiment of a method 300 in accordance with the present invention. The process starts with introducing a silicon substrate into a first processing chamber at step 310. In step 320, the surface of the substrate is cleaned to remove native oxides which may have formed on the surface of the substrate. In step 325, the substrate is transferred to a second processing chamber. About 5 Å to about 100 Å of hafnium silicate (HfSiOₓ) is grown on a silicon wafer at step 330. A detailed description of the surface cleaning and high-k dielectric layer formation is provided in United States Patent Application Publication No. 2003/0232501, filed Nov. 21, 2002, entitled “Surface Pre-Treatment For Enhancement Of Nucleation Of High Dielectric Constant Materials,” assigned to Applied Materials, Inc., and herein incorporated by reference. The hafnium silicate layer is one example of a material deposited using this method. The invention can be applied to other types of gate dielectrics, which could be a high-K dielectric material having a dielectric constant greater than 4.0.

In step 335, the substrate is transferred to an anneal chamber, such as the CENTURA™ RADIANCE™ rapid thermal processing (RTP) chamber available from Applied Materials, Inc., located in Santa Clara, Calif., for a post deposition annealing of the HfSiOₓ film. In step 340, a post deposition anneal is performed where the substrate is annealed at a temperature from about 500° C. to about 1200° C., preferably from about 550-700° C. for a time period from about 1 second to about 240 seconds, preferably from about 30 seconds to about 90 seconds, for example, at about 650° C. for about 60 seconds. Generally, the anneal chamber atmosphere contains at least one anneal gas, such as O₂, N₂, NH₃, N₂H₄, NO, N₂O, or combinations thereof. The anneal chamber is maintained at a pressure from about 5 Torr to about 100 Torr, for example, at about 50 Torr.

In step 345, the substrate is then transferred into a plasma chamber containing at least a nitrogen-containing gas where a voltage is induced on the wafer followed by plasma nitridation in step 350. The voltage is between about 300 V and about 5000 V, for example at about 1200 V. The plasma nitridation process continues for about 2 seconds to about 20 minutes to control the nitridation dose in HfSiOₓN_{y} formation in step 350. In step 355, the substrate is transferred back to the RTP processing chamber where a post nitridation anneal, step 360, is performed. During the post nitridation anneal, the substrate is annealed at a temperature from about 600° C. to about 1200° C., preferably from about 700-1100° C. for a time period from about 1 second to about 120 seconds, preferably from about 30 seconds to about 90 seconds, for example, at about 1000° C. for about 60 seconds. Generally, the anneal chamber atmosphere contains at least one anneal gas, such as O₂, N₂, NH₃, N₂H₄, NO, N₂O, or combinations thereof. The anneal chamber is maintained at a pressure from about 5 Torr to about 100 Torr, for example, at about 15 Torr. Alternatively, the post nitridation anneal comprises a two-step process in which an inert or reducing step is followed by an oxidizing step.

After forming the gate dielectric, a gate electrode, such as polysilicon may be deposited by low pressure chemical vapor deposition (LPCVD), atomic layer epitaxy (ALE), thermal decomposition methods, or other methods known in the art. The polysilicon layer generally contains dopants such as boron, phosphorous or arsenic. The gate electrode can also be a metal layer.

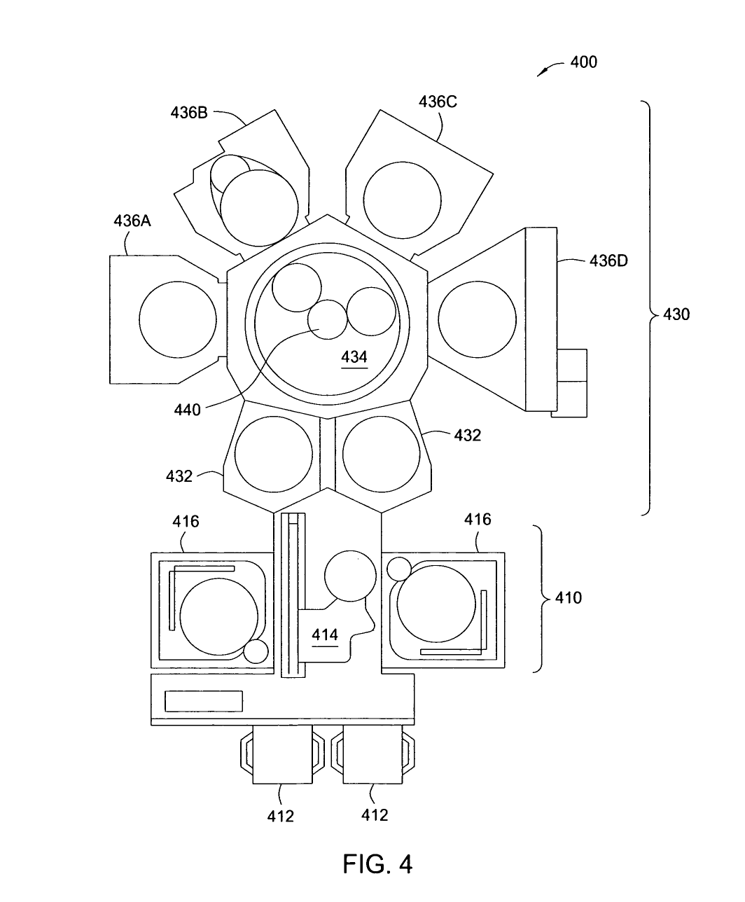

FIG. 4 is a schematic view of an integrated processing system 400 capable of performing the processes disclosed herein. FIG. 4 is a schematic top view of one embodiment of an integrated system 400 capable of performing the processes disclosed herein. The integrated system 400 comprises a cleaning module 410 and a thermal processing/deposition mainframe system 430. As shown in FIG. 4, the cleaning module 410 is an OASIS CLEAN™ system, available from Applied Materials, Inc., located in Santa Clara, Calif. The thermal processing/deposition mainframe system 430 is a CENTURA® system and is also commercially available from Applied Materials, Inc., located in Santa Clara, Calif. This particular embodiment of the system to perform the process as disclosed herein is provided to illustrate the invention and should not be used to limit the scope of the invention.

The cleaning module 410 generally includes one or more substrate cassettes 412, one or more transfer robots 414 disposed in a substrate transfer region, and one or more single-substrate clean chambers 416. Other aspects and embodiments of a single-substrate clean system are disclosed in U.S. patent application Ser. No. 09/891,849, entitled “Method and Apparatus for Wafer Cleaning, filed Jun. 25, 2001 and in U.S. patent application Ser. No. 09/891,791, entitled “Wafer Spray Configurations for a Single Wafer Processing Apparatus,” filed Jun. 25, 2001, both of which are herein incorporated by reference in their entirety to the extent not inconsistent with the present disclosure.

The thermal processing/deposition mainframe system 430 generally includes load lock chambers 432, a transfer chamber 434, and processing chambers 436A, 436B, 436C, and 436D. The transfer chamber 434 is preferably between 1 mTorr to about 100 Torr and preferably comprises a non-reactive gas ambient, such as a N₂ ambient. The load lock chambers 432 allow for the transfer of substrates into and out from the thermal processing/deposition mainframe system 430 while the transfer chamber 434 remains under a low pressure non-reactive environment. The transfer chamber includes a robot 440 having one or more blades which transfers the substrates between the load lock chambers 432 and processing chambers 436A, 436B, 436C, and 436D. Any of the processing chambers 436A, 436B, 436C, or 436D may be removed from the thermal processing/deposition mainframe system 430 if not necessary for the particular process to be performed by the system 430.

It is believed that it is advantageous to perform the pre-treatment step 320 (FIG. 3) and the high-K dielectric layer formation 330 (FIG. 3) on a mainframe system to reduce the formation of native oxides and/or contamination of the pre-treated surface of a substrate prior to formation of the high-K dielectric layer. In other embodiments, the pre-treatment step may include polishing, etching, reduction, oxidation, hydroxylation, annealing and/or baking. Exposing the substrate to air between the pre-treatment step 320 and the high-K dielectric layer formation 330 may reduce the effectiveness of nucleation thereover of high-K dielectric materials. It is optional to have the cleaning module 410 coupled with mainframe system 430 as shown in FIG. 4 to further reduce the formation of native oxides over and/or contamination of substrates between cleaning steps and other processing steps. Of course, in other embodiments, cleaning steps may be performed in a cleaning module separate from the thermal processing/deposition mainframe system.

One embodiment of the integrated processing system 400 configured to form a high-K dielectric layer comprises processing chamber 436A adapted to perform the Decoupled Plasma Nitridation process as described above, processing chamber 436B adapted to perform a process such as a chemical vapor deposition chamber or an atomic layer deposition chamber, adapted to deposit a high dielectric constant material, such as a hafnium containing layer. In another embodiment, processing chamber 436C comprises a rapid thermal processing (RTP) chamber where the structure may be annealed. The RTP chamber may be a XE, XE Plus or Radiance chamber available from Applied Materials, Inc. In another embodiment, processing chamber 436D comprises a low pressure chemical vapor deposition chamber (LPCVD), such as a POLYgen chamber, available from Applied Materials, Inc, adapted to deposit a gate dielectric layer. Other embodiments of the system 400 are within the scope of the present invention. For example, the position of a particular processing chamber on the system may be altered or the number of processing chamber may be altered.

While the above embodiments are described with respect to FIGS. 3 and 4, it is recognized that other integrated processing systems and chamber combinations may be used with the embodiments described herein. Furthermore, any number of processing chambers may be part of a non-integrated system.

Performance of the Chucked DPN Process for Gate Dielectrics

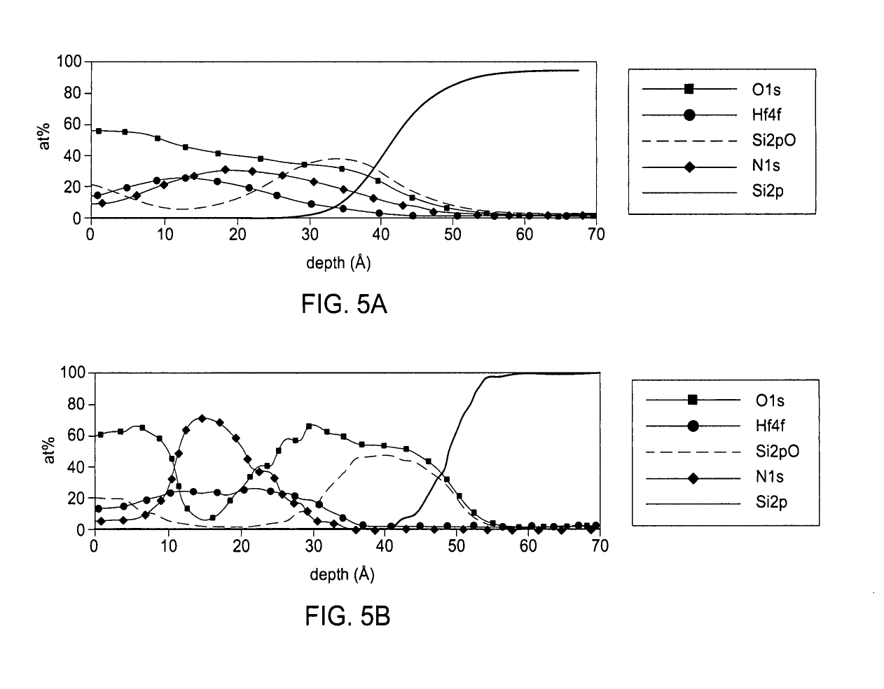

FIG. 5A shows oxygen, hafnium, oxidized silicon, nitrogen, and silicon concentration profiles for a chuckless plasma nitridation process. The following process sequence yielded the results for the chuckless process in FIG. 5A. The nitridation process was performed for a time period of 128 seconds with a plasma power setting of 900 watts. The flow rate of nitrogen was 63 sccm and the flow rate of argon was 137 sccm. During this chuckless process there was no flow of helium onto the wafer surface.

In FIG. 5A, the x-axis represents the depth of nitrided high-k film in Angstroms (Å). The gate dielectric/high-k interface is located at about 0 Å and the high-k/channel interface is located at about 50 Å. The y-axis represents the atomic percent (at %) of oxygen, hafnium, oxidized silicon, nitrogen, and silicon present in the high-k film. From a depth of about 0 Å to about 50 Å, the nitrogen concentration ranges from about 5 at % to about 25 at %. As FIG. 5A demonstrates, at 10 Å there is about 20 at % nitrogen; at 20 Å there is about 28 at % nitrogen; at 30 Å there is about 20 at % nitrogen; at 40 Å there is about 10 at % nitrogen; and at 50 Å there is less than about 5%.

FIG. 5B shows oxygen, hafnium, oxidized silicon, nitrogen, and silicon concentration profiles for a chucked plasma nitridation process. The following process sequence yielded the results for the chuckless process in FIG. 5B. The nitridation process was performed for a time period of 128 seconds with a plasma power setting of 900 watts. The flow rate of nitrogen was 63 sccm and the flow rate of argon was 137 sccm. During this chucked process 1200 V was applied to the wafer and helium at a pressure of 4 T was blown over the wafer surface. This process sequence was identical to the process sequence in FIG. 5A except for the voltage and helium applied to the wafer.

In FIG. 5B, the x-axis represents the depth of nitrided high-k film in Angstroms (Å). The gate dielectric/high-k interface is located at about 0 Å and the high-k/channel interface is located at about 50 Å. The y-axis represents the atomic percent (at %) of oxygen, hafnium, oxidized silicon, nitrogen, and silicon present in the film. From a depth of about 0 Å to about 50 Å, the nitrogen concentration ranges from about 0 at % to about 70 at %. As FIG. 5B demonstrates, at 10 Å there is about 20 at % nitrogen; at 15 Å there is about 70 at %; at 20 Å there is about 50 at % nitrogen; at 30 Å there is about 5 at % nitrogen; at 40 Å there is about 0 at % nitrogen; and at 50 Å there is about 0 at % nitrogen.

A comparison of the chuckless process in FIG. 5A with the chucked process in FIG. 5B demonstrates that the chucked process provides the more desirable results of a localized nitrogen concentration in the high-k film and a decreased nitrogen concentration at the high-k/channel interface. Thus the chucked process achieves the objectives of reducing gate leakage and increasing mobility.

While the foregoing is directed to embodiments of the present invention, other and further embodiments of the invention may be devised without departing from the basic scope thereof, and the scope thereof is determined by the claims that follow.

1. A method of forming a nitrided gate dielectric, comprising:
providing a substrate comprising a gate dielectric film;
inducing a voltage on the substrate; and
exposing the substrate to a plasma comprising a nitrogen source while maintaining the voltage to form a nitrided gate dielectric on the substrate.

2. The method of claim 1, wherein the voltage comprises a continuous DC bias voltage.

3. The method of claim 1, wherein the voltage is less than about 5000 V.

4. The method of claim 3, wherein the voltage is less than about 1200 V.

5. The method of claim 1, wherein the inducing a voltage on the substrate comprises applying a DC bias voltage to an electrostatic chuck supporting the substrate.

6. The method of claim 1, wherein the inducing a voltage on the substrate comprises applying a DC bias voltage to an electrode positioned adjacent the substrate.

7. The method of claim 6, wherein the electrode comprises an annular shape, a D-shape, or a shape interdigitated with another electrode.

8. The method of claim 1 wherein the gate dielectric is selected from the group consisting of silicon dioxide, silicon oxynitride, silicon nitride, hafnium oxide, hafnium silicate, hafnium silicon oxynitride, zirconium oxide, zirconium silicate, barium strontium titanate, and lead zirconate titanate.

9. The method of claim 1 wherein the plasma is provided by applying a power to a plasma power source selected from the group consisting of an inductively coupled power source, a capacitively coupled power source, a surface wave power source, a microwave power source, an electronic cyclotron resonance and a magnetron or modified magnetron-type source.

10. The method of claim 1, wherein the exposing the substrate to a plasma process occurs at pressure between about 1 mTorr and about 1 Torr.

11. The method of claim 1, wherein the process gas for the nitrogen-containing plasma comprises at least one of nitrogen and ammonia gases at a flow rate between about 50 sccm and 20 slm.

12. A method of forming a nitrided gate dielectric, comprising:
providing a substrate comprising a gate dielectric film;
inducing a voltage on the substrate by applying a voltage to an electrostatic chuck supporting the substrate; and
exposing the substrate to a plasma comprising a nitrogen source to form a nitrided gate dielectric on the substrate.

13. The method of claim 12, wherein the voltage comprises a continuous DC bias voltage less than 5000 V.

14. The method of claim 13, wherein the voltage is less than 1200 V.

15. The method of claim 12, wherein the exposing the substrate to a plasma occurs for a time period between about 2 seconds and about 360 seconds with a plasma power setting of about 900 watts.

16. The method of claim 12 wherein the gate dielectric is selected from the group consisting of silicon dioxide, silicon oxynitride, silicon nitride, hafnium oxide, hafnium silicate, hafnium silicon oxynitride, zirconium oxide, zirconium silicate, barium strontium titanate and lead zirconate titanate.

17. A method of forming a nitrided gate dielectric in an integrated processing system comprising:
introducing a substrate comprising silicon into a first processing chamber of an integrated processing system;
forming a dielectric film on the substrate;
transferring the substrate to a second processing chamber of the integrated processing system;
annealing the substrate;
transferring the substrate to a third processing chamber of the integrated processing system;
inducing a voltage on the substrate; and
exposing the substrate to a plasma comprising a nitrogen source to form a nitrided gate dielectric on the substrate.

18. The method of claim 17, further comprising:
transferring the substrate to the second processing chamber of the integrated processing system; and
annealing the substrate.

19. The method of claim 18, further comprising:
transferring the substrate to a fourth processing chamber of the integrated processing system; and
depositing a polysilicon layer on the substrate.

20. The method of claim 19, wherein the inducing the voltage on the substrate comprises applying a bias voltage less than 1200 V at a pressure of 4 Torr of helium.
